(19) United States
(12) Patent Application Publication
(10) Pub. No.: US 2026/0231525 A1
(43) Pub. Date: Aug. 6, 2026

(54) TRANSISTOR DEVICE

(71) Applicant: PEKING UNIVERSITY, Beijing (CN)

(72) Inventors: Jin WEI, Beijing (CN); Junjie YANG, Beijing (CN)

(73) Assignee: PEKING UNIVERSITY, Beijing (CN)

(21) Appl. No.: 19/146,125

(22) PCT Filed: Jan. 11, 2024
(86) PCT No.: PCT/CN2024/071784

§ 371 Date: Jul. 7, 2025

(30) Foreign Application Priority Data
Jan. 13, 2023 (CN) 202310070217.9

(51) Int. Cl. H10D 84/86; H10D 30/47; H10D 62/85

(52) U.S. Cl. CPC H10D 84/86; H10D 30/475; H10D 62/8503

(57) ABSTRACT

A transistor device is provided. The transistor device includes a high electron mobility transistor, and a first depletion-mode transistor or a resistor. The high electron mobility transistor includes a first source electrode, a first drain electrode, and a first gate electrode; the first gate electrode includes an Ohmic contact electrode, a dielectric layer, and a conductive interconnect component that are provided on the gate cap layer; the first depletion-mode transistor includes a second source electrode, a second drain electrode, and a second gate electrode; the second gate electrode is connected with the second source electrode; one of the second source electrode and the second drain electrode is connected with the Ohmic contact electrode, and the other of the second source electrode and the second drain electrode is connected with the conductive interconnect component.

### CROSS-REFERENCE TO RELATED APPLICATIONS

This application is a U.S. national stage application of International Patent Application No. PCT/CN2024/071784, filed on Jan. 11, 2024, which claims the priority to Chinese Patent Application No. 202310070217.9, filed on Jan. 13, 2023. All the aforementioned patent applications are hereby incorporated by reference in their entireties.

### TECHNICAL FIELD

Embodiments of the present disclosure relate to a transistor device.

### BACKGROUND

In a gallium nitride (GaN) device, a polarization effect is utilized to form a high mobility two-dimensional electron gas channel between a barrier layer and a channel layer, thereby realizing the preparation of a high electron mobility transistor (HEMT). Therefore, GaN HEMT may achieve low ON resistance and high operating frequency. In order to prepare a highly stable and enhanced GaN HEMT device, P-type doped gallium nitride (p-GaN) is usually used as a gate electrode of the device.

At present, one structure is an Ohmic contact p-GaN HEMT device, where the gate metal forms an Ohmic contact with the p-GaN. Another structure is a Schottky contact p-GaN HEMT device, where the gate metal forms a Schottky contact with the p-GaN.

However, in the Ohmic contact p-GaN HEMT, the gate driving voltage cannot exceed 3 V, making the design of the drive circuit more complex. In the Schottky contact p-GaN HEMT, there is an issue of threshold voltage shift, leading to problems such as unintended turn-on or incomplete turn-on of the device.

### SUMMARY

At least one of the present disclosure provides a transistor device, including: a substrate; a high electron mobility transistor provided on the substrate; and a first depletion-mode transistor or a resistor provided on the substrate; where the high electron mobility transistor includes a barrier layer, a first source electrode, a first drain electrode, and a first gate electrode; the first source electrode and the first drain electrode are provided within an active region on the barrier layer; the first gate electrode is located between the first source electrode and the first drain electrode; the first source electrode, the first gate electrode, and the first drain electrode are isolated from each other by an insulation layer; and the first gate electrode includes a gate cap layer provided on the barrier layer, as well as an Ohmic contact electrode, a dielectric layer, and a conductive interconnect component that are provided on the gate cap layer; the first depletion-mode transistor includes a second source electrode, a second drain electrode, and a second gate electrode; the second gate electrode is connected with the second source electrode; one of the second source electrode and the second drain electrode is connected with the Ohmic contact electrode, and the other of the second source electrode and the second drain electrode is connected with the conductive interconnect component; the resistor includes a first electrode and a second electrode opposite to each other; the first electrode is connected with the Ohmic contact electrode, and the second electrode is connected with the conductive interconnect component.

For example, the transistor device provided by at least one embodiment of the present disclosure includes the high electron mobility transistor and the first depletion-mode transistor, where the second source electrode, the second drain electrode, and the second gate electrode are provided on the barrier layer; the second gate electrode is located between the second source electrode and the second drain electrode; and the second source electrode, the second gate electrode and the second drain electrode are isolated from each other by the insulation layer.

For example, the transistor device provided by at least one embodiment of the present disclosure further includes a second depletion-mode transistor provided on the substrate, where the second depletion-mode transistor includes a third source electrode, a third drain electrode and a third gate electrode; the third gate electrode is connected with the first source electrode; one of the third source electrode and the third drain electrode is connected with the Ohmic contact electrode; and the second depletion-mode transistor is electrically connected with the first depletion-mode transistor through the Ohmic contact electrode; the other of the third source electrode and the third drain electrode is connected with the conductive interconnect component, and the second depletion-mode transistor is electrically connected with the first depletion-mode transistor through the conductive interconnect component.

For example, the transistor device provided by at least one embodiment of the present disclosure includes the high electron mobility transistor and the resistor, where the first electrode and the second electrode are provided on the barrier layer.

For example, the transistor device provided by at least one embodiment of the present disclosure further includes a second depletion-mode transistor provided on the substrate, where the second depletion-mode transistor includes a third source electrode, a third drain electrode and a third gate electrode; one of the third source electrode and the third drain electrode is connected with the Ohmic contact electrode, and the second depletion-mode transistor is electrically connected with the first electrode through the Ohmic contact electrode; the other of the third source electrode and the third drain electrode is connected with the conductive interconnect component, and the second depletion-mode transistor is electrically connected with the second electrode through the conductive interconnect component.

For example, in the transistor device provided by at least one embodiment of the present disclosure, the third source electrode, the third drain electrode and the third gate electrode are provided on the barrier layer; the third gate electrode is located between the third source electrode and the third drain electrode; and the third source electrode, the third gate electrode and the third drain electrode are isolated from each other by the insulation layer.

For example, in the transistor device provided by at least one embodiment of the present disclosure, a material of the gate cap layer includes at least one of gallium nitride, aluminum gallium nitride, indium gallium nitride, and indium aluminum gallium nitride, where the gate cap layer is doped with P-type dopant.

For example, in the transistor device provided by at least one embodiment of the present disclosure, a material of the dielectric layer includes at least one of silicon dioxide, aluminum oxide, silicon nitride, aluminum nitride, and hafnium oxide.

For example, the transistor device provided by at least one embodiment of the present disclosure further includes a channel layer provided between the substrate and the barrier layer, where a material of the channel layer includes gallium nitride.

For example, in the transistor device provided by at least one embodiment of the present disclosure, a gate driving voltage swing of the transistor device is larger than 7 volts.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1 is a cross-sectional view of an exemplary transistor device provided by at least one embodiment of the present disclosure.

FIG. 2 is a cross-sectional view of an exemplary first depletion-mode transistor provided by at least one embodiment of the present disclosure.

FIG. 3 is a cross-sectional view of another exemplary transistor device provided by at least one embodiment of the present disclosure.

FIG. 4 is a cross-sectional view of an exemplary resistor integrated with a high electron mobility transistor provided by at least one embodiment of the present disclosure.

FIG. 5A is a cross-sectional view of still another exemplary transistor device provided by at least one embodiment of the present disclosure.

FIG. 5B is a circuit schematic diagram of an exemplary transistor device provided by at least one embodiment of the present disclosure.

FIG. 6 is a cross-sectional view of still another exemplary transistor device provided by at least one embodiment of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

The present disclosure is described below through several specific embodiments. In order to keep the following description of the embodiments of the present disclosure clear and concise, detailed descriptions of known functions and components may be omitted. When any component of the embodiments of the present disclosure appears in more than one of the drawings, the component is indicated by the same or similar reference mark in each of the drawings.

At least one embodiment of the present disclosure provides a transistor device, including: a substrate; a high electron mobility transistor provided on the substrate; and a first depletion-mode transistor or a resistor provided on the substrate; where the high electron mobility transistor includes a barrier layer, a first source electrode, a first drain electrode, and a first gate electrode; the first source electrode and the first drain electrode are provided within an active region on the barrier layer; the first gate electrode is located between the first source electrode and the first drain electrode; the first source electrode, the first gate electrode, and the first drain electrode are isolated from each other by an insulation layer; and the first gate electrode includes a gate cap layer provided on the barrier layer, as well as an Ohmic contact electrode, a dielectric layer, and a conductive interconnect component that are provided on the gate cap layer; the first depletion-mode transistor includes a second source electrode, a second drain electrode, and a second gate electrode; the second gate electrode is connected with the second source electrode; one of the second source electrode and the second drain electrode is connected with the Ohmic contact electrode, and the other of the second source electrode and the second drain electrode is connected with the conductive interconnect component; the resistor includes a first electrode and a second electrode opposite to each other; the first electrode is connected with the Ohmic contact electrode, and the second electrode is connected with the conductive interconnect component.

In a transistor device provided by at least one embodiment of the present disclosure, a structure consists of Ohmic contact electrode, dielectric layer and conductive-interconnect component, is adopted on a gate cap layer of a high electron mobility transistor; and the structure is at least connected with a first depletion-mode transistor or a resistor, which can increase driving voltage swing of the high electron mobility transistor and reduce a gate current of the high electron mobility transistor. During a turn-on process of the device, due to the presence of the Ohmic contact electrode, charges stored in the gate cap layer of the high electron mobility transistor are released, thereby eliminating threshold voltage shift and improving dynamic stability of the high electron mobility transistor. When the gate voltage further increases, the first depletion-mode transistor or the resistor can withstand the excessively high gate voltage. For example, the current of the first depletion-mode transistor would be saturated when the device is pinched off, thereby effectively suppressing the gate current and increasing the gate voltage swing of the high electron mobility transistor. Moreover, a large capacitor is formed between the conductive interconnect component and the Ohmic contact electrode through the dielectric layer, which can significantly accelerate a switching speed of the device.

The structure of the transistor device will be described in detail below with reference to several embodiments.

FIG. 1 is a cross-sectional view of an exemplary transistor device provided by at least one embodiment of the present disclosure. As shown in FIG. 1, the transistor device includes a substrate, one high electron mobility transistor provided on the substrate, and one first depletion-mode transistor.

For example, as shown in FIG. 1, the high electron mobility transistor may include a channel layer and a barrier layer prepared on the substrate; and the channel layer and the barrier layer may be sequentially stacked on the substrate. For example, the high electron mobility transistor may further include a transition layer, a buffer layer, as well as structures such as an insulation layer and a field plates, etc. necessary in a traditional HEMT device. For example, the transition layer, the buffer layer, the channel layer, and the barrier layer may be sequentially stacked on the substrate.

For example, as shown in FIG. 1, the high electron mobility transistor includes a first source electrode S, a first drain electrode D, and a first gate electrode G. The first source electrode S and the first drain electrode D are provided within an active region on the barrier layer. For example, the first source electrode S and the first drain electrode D are prepared on the barrier layer by using Ohmic contact. For example, the first gate electrode G is located between the first source electrode S and the first drain electrode D. The first gate electrode G includes a gate cap layer provided on the barrier layer, as well as an Ohmic contact electrode E01, a dielectric layer D01, and a conductive interconnect component N02 that are provided on the gate cap layer. The conductive interconnect component N02 may be any conductive metal. For example, the first source electrode S, the first gate electrode G, and the first drain electrode D of the high electron mobility transistor are isolated from each other by an insulation layer. N01 in FIG. 1 refers to interconnect metal, which may be used for connecting an external circuit or other component. The interconnect metal may be any conductive metal.

For example, in some embodiments of the present disclosure, the gate cap layer may be prepared with a semiconductor material with P-type doping; and the semiconductor material here includes at least one of materials such as gallium nitride (GaN), aluminum gallium nitride, indium gallium nitride, and indium aluminum gallium nitride. For example, the substrate may be one or more of a silicon substrate, a sapphire substrate, an aluminum nitride substrate, or a silicon carbide substrate. For example, the transition layer is used for balancing lattice and stress mismatches in epitaxy layers, and may be formed of aluminum nitride, gallium nitride, or a mixture of both. For example, the buffer layer is used for reducing an OFF-state leakage current of the device and increasing a breakdown voltage of the device. The buffer layer is a high resistance layer and may be doped with carbon or iron. For example, the main material of the buffer layer may be aluminum nitride, gallium nitride, or a mixture of both. For example, the channel layer provides a conductive channel for two-dimensional electron gas. The material of the channel layer may be gallium nitride. For example, the material of the barrier layer may include at least one of aluminum gallium nitride, aluminum nitride, indium nitride, and aluminum indium gallium nitride, or a mixture thereof. The barrier layer may provide two-dimensional electron gas through the polarization effect. For example, the material of the insulation layer may include at least one of aluminum oxide (Al₂O₃), silicon dioxide (SiO₂), silicon nitride (SiN), aluminum nitride (AlN), hafnium oxide (HfO₂), etc. The material of the dielectric layer D01 includes at least one of silicon dioxide, aluminum oxide, silicon nitride, aluminum nitride, hafnium oxide, or may also be one of other dielectric materials. The material of the conductive interconnect component N02 may include any conductive material, for example, a conductive metal.

For example, in the embodiment of the present disclosure, the first depletion-mode transistor includes a second source electrode S1, a second drain electrode D1, and a second gate electrode G1. The second gate electrode G1 is connected with the second source electrode S1. One of the second source electrode S1 and the second drain electrode D1 is connected with the Ohmic contact electrode E01, and the other of the second source electrode S1 and the second drain electrode D1 is connected with the conductive interconnect component N02. In one example, as shown in FIG. 1, the second source electrode S1 is connected with the Ohmic contact electrode E01 of the high electron mobility transistor; and the second drain electrode D1 is connected with the conductive interconnect component N02 of the high electron mobility transistor. In another example, the second source electrode S1 is connected with the conductive interconnect component N02 of the high electron mobility transistor; and the second drain electrode D1 is connected with the Ohmic contact electrode E01 of the high electron mobility transistor. For example, the connection between the first depletion-mode transistor and the conductive interconnect component N02 of the high electron mobility transistor may be achieved through layout design, with interconnection completed outside the device.

For example, in the embodiment of the present disclosure, the high electron mobility transistor may be a GaN HEMT, and the transistor device may be a GaN transistor device.

For example, in the embodiment of the present disclosure, the material of an active layer in the first depletion-mode transistor may include at least one of silicon, silicon carbide, gallium nitride, and gallium arsenide.

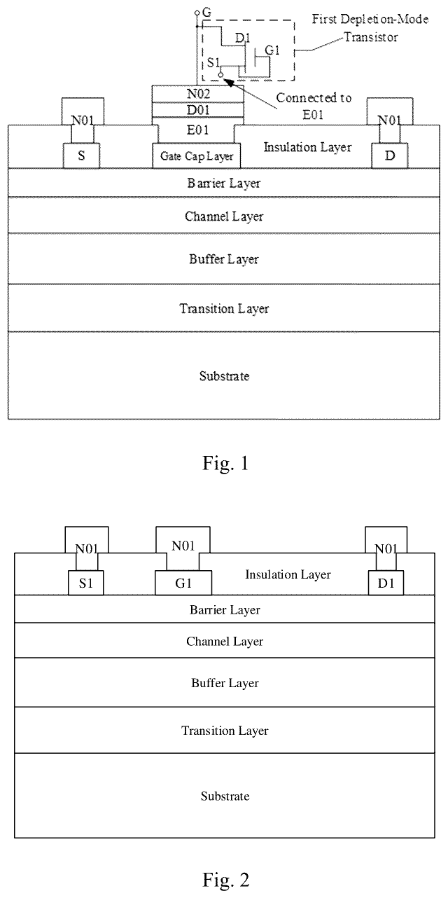

FIG. 2 is a cross-sectional view of an exemplary first depletion-mode transistor provided by at least one embodiment of the present disclosure. As shown in FIG. 2, the second gate electrode G1 of the first depletion-mode transistor is located between the second source electrode S1 and the second drain electrode D1. The second source electrode S1, the second gate electrode G1, and the second drain electrode D1 are isolated from each other by an insulation layer. N01 in FIG. 2 refers to interconnect metal, which may be used for connecting an external circuit or other component. The interconnect metal may be any conductive metal. The material of the interconnect metal in FIG. 2 may be the same or different from the material of the interconnect metal in FIG. 1.

For example, the second source electrode S1, the second drain electrode D1 and the second gate electrode G1 of the first depletion-mode transistor may be provided on the barrier layer. Moreover, the first depletion-mode transistor may be integrated with the high electron mobility transistor on a same platform to reduce parasitic effects. For example, the materials of the substrate, the transition layer, the buffer layer, the channel layer, the barrier layer, and the insulation layer, etc. of the first depletion-mode transistor may be the same as the materials of the respective layers of the high electron mobility transistor, and may be formed in the corresponding same process steps. For example, the second gate electrode G1 of the first depletion-mode transistor may be a structure such as p-GaN, metal-insulation layer-semiconductor (MIS), Schottky junction, etc.

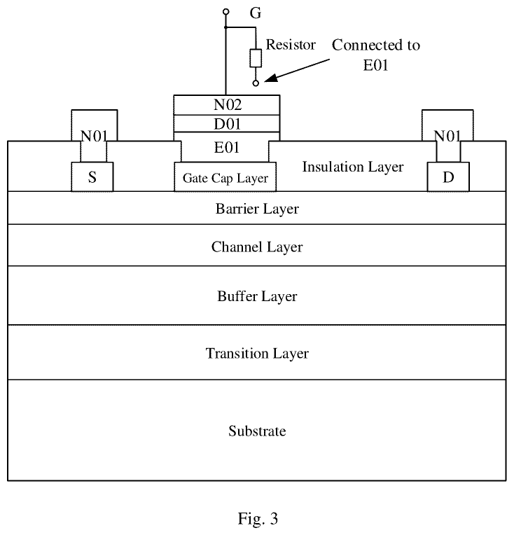

FIG. 3 is a cross-sectional view of another exemplary transistor device provided by at least one embodiment of the present disclosure. As shown in FIG. 3, the transistor device includes a high electron mobility transistor and a resistor; the resistor has one terminal (e.g., a first electrode) connected with the Ohmic contact electrode E01 of the high electron mobility transistor, and the other terminal (e.g., a second electrode) connected with the conductive interconnect component N02 of the high electron mobility transistor. A gate current of the high electron mobility transistor may be limited by the resistor; and connection between the resistor and the Ohmic contact electrode E01 may be achieved through layout design, with interconnection completed outside the device.

In one example of the embodiment of the present disclosure, the first electrode and the second electrode of the resistor may be provided on the barrier layer of the high electron mobility transistor, so as to be integrated with the high electron mobility transistor and reduce process complexity. For example, in the example, the resistor may be prepared with a gallium nitride material.

In another example of the embodiment of the present disclosure, the resistor may serve as a discrete device to be connected with the high electron mobility transistor, thereby improving flexibility of circuit design and being applicable to various preparation methods. For example, the resistor may be connected with the high electron mobility transistor by means of soldering. The resistor may be any type of resistor, for example, the resistor may be made of a gallium nitride material or a non-gallium nitride material.

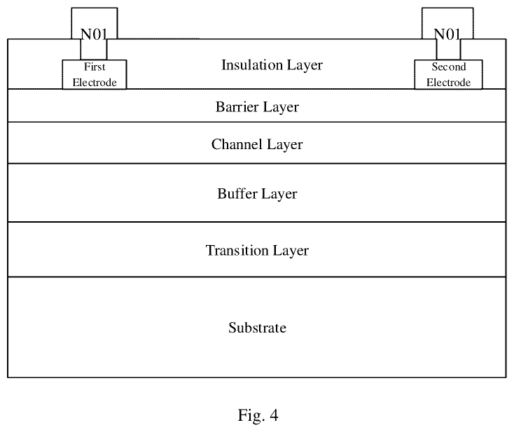

FIG. 4 is a cross-sectional view of an exemplary resistor integrated with a high electron mobility transistor provided by at least one embodiment of the present disclosure. As shown in FIG. 4, the resistor includes the first electrode and the second electrode opposite to each other. The first electrode and the second electrode are isolated from each other by an insulation layer. For example, the first electrode of the resistor and the first source electrode S of the high electron mobility transistor may be formed by using a same process step with a same material; and the second electrode of the resistor and the first drain electrode D of the high electron mobility transistor may be formed by using a same process step with a same material. For example, a size of the resistor may be adjusted by changing a distance between the first electrode and the second electrode or a width of an active region.

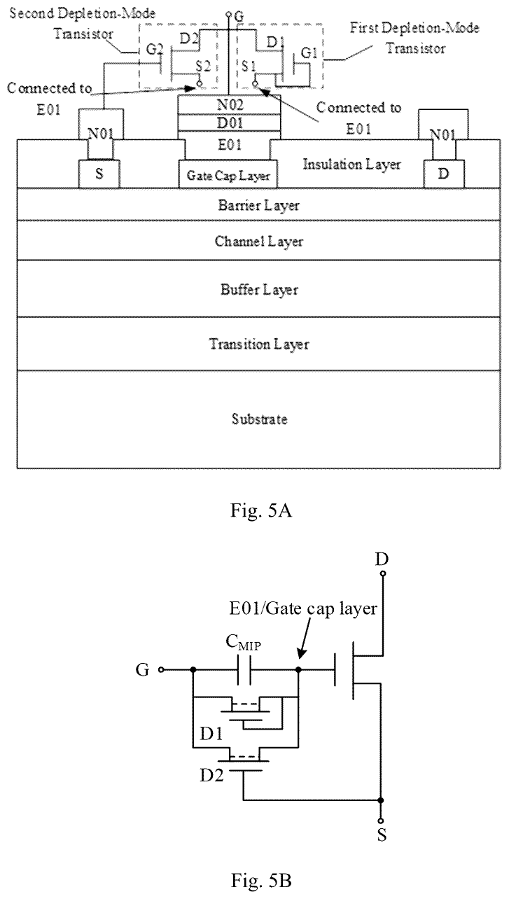

FIG. 5A is a cross-sectional view of still another exemplary transistor device provided by at least one embodiment of the present disclosure. As shown in FIG. 5A, the transistor device according to this embodiment includes one high electron mobility transistor and two depletion-mode transistors, namely, a first depletion-mode transistor and a second depletion-mode transistor.

For example, the second depletion-mode transistor includes a third source electrode S2, a third drain electrode D2, and a third gate electrode G2. The third gate electrode G2 is located between the third source electrode S2 and the third drain electrode D2. The third gate electrode G2 is connected with the first source electrode S. One of the third source electrode S2 and the third drain electrode D2 is connected with the Ohmic contact electrode E01, and the second depletion-mode transistor is electrically connected with the first depletion-mode transistor through the Ohmic contact electrode E01. The other of the third source electrode S2 and the third drain electrode D2 is connected with the conductive interconnect component, and the second depletion-mode transistor is electrically connected with the first depletion-mode transistor through the conductive interconnect component N02. For example, as shown in FIG. 5A, the third source electrode S2 is connected with the Ohmic contact electrode E01 of the high electron mobility transistor; the third gate electrode G2 is connected with the first source electrode S of the high electron mobility transistor; and the third drain electrode D2 is connected with the conductive interconnect component N02 of the high electron mobility transistor. The structure of the first depletion-mode transistor is the same as the structure in FIG. 2, which will not be described in detail here.

For example, the second depletion-mode transistor may have a structure substantially identical to that of the first depletion-mode transistor shown in FIG. 1, and the two only differ in that the second gate electrode G1 and the second source electrode S1 of the first depletion-mode transistor shown in FIG. 1 are short circuited, while the third gate electrode G2 and the third source electrode S2 of the second depletion-mode transistor are not short circuited.

As shown in FIG. 5A, the second source electrode S1 of the first depletion-mode transistor is connected with the third source electrode S2 of the second depletion-mode transistor, the third gate electrode G2 of the second depletion-mode transistor is connected with the first source electrode S of the high electron mobility transistor, and the second gate electrode G1 of the first depletion-mode transistor is connected with the second source electrode S1. The conductive interconnect component N02 of the high electron mobility transistor is connected with both the second drain electrode D1 of the first depletion-mode transistor and the third drain electrode D2 of the second depletion-mode transistor. For example, the gate cap layer, the conductive interconnect component N02, the dielectric layer D01, and the Ohmic contact electrode E01 together form the first gate electrode G of the high electron mobility transistor. For example, the second source electrode S1 of the first depletion-mode transistor and the third source electrode S2 of the second depletion-mode transistor are both connected with the Ohmic contact electrode E01 of the high electron mobility transistor; and the connection may be achieved through layout design, with interconnection completed outside the device.

For example, as shown in FIG. 5A, the third source electrode S2, the third drain electrode D2, and the third gate electrode G2 of the second depletion-mode transistor may be provided on the barrier layer, that is, the second depletion-mode transistor may be integrated with the high electron mobility transistor on a same platform to reduce a parasitic effect. For example, the third source electrode S2, the third gate electrode G2, and the third drain electrode D2 are isolated from each other by an insulation layer. The materials of the substrate, the transition layer, the buffer layer, the GaN channel layer, the barrier layer, and the insulation layer, etc. of the second depletion-mode transistor may be correspondingly the same as the materials of the respective layers of the high electron mobility transistor. For example, the gate electrode of the second depletion-mode transistor may be a structure such as p-GaN, MIS, Schottky junction, etc.

FIG. 5B is a circuit schematic diagram of an exemplary transistor device provided by at least one embodiment of the present disclosure. As shown in FIG. 5B, the Ohmic contact electrode E01, the dielectric layer D01, and the conductive interconnect component N02 form an AC-coupled capacitor CMIP, which can improve the driving speed of the gate electrode and accelerate switching speed of the device. The first depletion-mode transistor and the second depletion-mode transistor are connected in parallel. The presence of the first depletion-mode transistor can increase the driving voltage swing and reduce the gate current of the high electron mobility transistor.

For example, during the switching process of the transistor device, due to the presence of the Ohmic contact electrode E01, charges stored in the gate cap layer of the high electron mobility transistor are released, thereby eliminating threshold voltage instability. When the gate voltage further increases, the current of first depletion-mode transistor is saturated when the device is pinched off. Therefore, the first depletion-mode transistor can withstand the excessive gate voltage and thereby effectively suppress the gate current, improving dynamic stability and gate during swing of the transistor device.

For example, the gate driving voltage swing of the transistor device and the capacitance value of the AC-coupled capacitor C_{MIP} could be controlled by changing the material or the thickness, etc. of the dielectric layer D01. For example, in at least one example of the embodiment of the present disclosure, the gate driving voltage swing of the transistor device may be larger than 7 volts (V), up to tens of volts or even higher, for example, up to 25 V.

During turn-off process of the transistor device, when the gate bias is 0 V, since the second depletion-mode transistor is a normally-on device, positive charges accumulated in the gate cap layer of the high electron mobility transistor during the switching process can be released, thereby effectively accelerating the turn-off process of the transistor device.

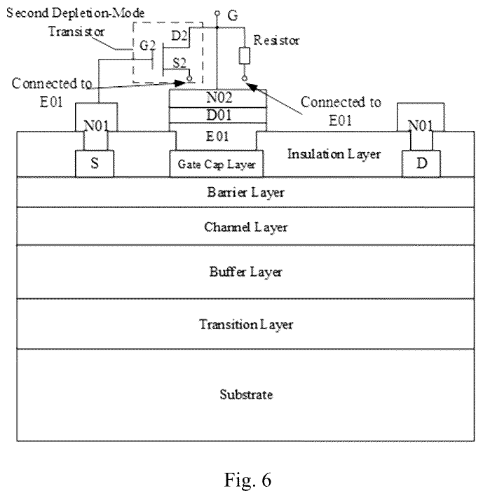

FIG. 6 is a cross-sectional view of still another exemplary transistor device provided by at least one embodiment of the present disclosure. As shown in FIG. 6, the transistor device adopts one resistor and one second depletion-mode transistor. The structure of the second depletion-mode transistor is consistent with the structure of the second depletion-mode transistor shown in FIG. 5A. The structure of the resistor is consistent with the structure of the resistor shown in FIG. 4. Both the resistor and the second depletion-mode transistor may be integrated with the high electron mobility transistors, which will not be described in detail here.

For example, one of the third source electrode S2 and the third drain electrode D2 of the second depletion-mode transistor is connected with the first electrode of the resistor, and the other of the third source electrode S2 and the third drain electrode D2 of the second depletion-mode transistor is connected with the second electrode of the resistor.

For example, in one example, the third drain electrode D2 of the second depletion-mode transistor may be connected with the first electrode of the resistor, and the third source electrode S2 of the second depletion-mode transistor may be connected with the second electrode of the resistor. For example, in another example, the third drain electrode D2 of the second depletion-mode transistor may be connected with the second electrode of the resistor, and the third source electrode S2 of the second depletion-mode transistor may be connected with the first electrode of the resistor.

For example, one of the third source electrode S2 and the third drain electrode D2 of the second depletion-mode transistor is connected with the Ohmic contact electrode E01, and the other of the third source electrode S2 and the third drain electrode D2 is connected with the conductive interconnect component N02. For example, the second depletion-mode transistor is electrically connected with the first electrode of the resistor through the Ohmic contact electrode E01, and is electrically connected with the second electrode of the resistor through the conductive interconnect component N02.

For example, as shown in FIG. 6, the third gate electrode G2 of the second depletion-mode transistor is connected with the first source electrode S of the high electron mobility transistor. One terminal (e.g., the first electrode) of the resistor is connected with the third drain electrode D2 of the second depletion-mode transistor, and the conductive interconnect component N02 of the high electron mobility transistor is connected with the third drain electrode D2 of the second depletion-mode transistor and the first electrode of the resistor. For example, the gate cap layer, the conductive interconnect component N02, the dielectric layer D01, and the Ohmic contact electrode E01 together form the first gate electrode G of the high electron mobility transistor. The third source electrode S2 of the second depletion-mode transistor and the other terminal (e.g., the second electrode) of the resistor are both connected with the Ohmic contact electrode E01 of the high electron mobility transistor; and the connection may be achieved through layout design, with interconnection completed outside the device.

Although the present disclosure has been described in detail above using general descriptions and specific implementation methods, it is obvious to those skilled in the art that some modifications or improvements can be made to the embodiments of the present disclosure. Therefore, these modifications or improvements made without departing from the spirit of the present disclosure are within the scope of protection claimed by the present disclosure.

For the present disclosure, the following points need to be explained:
(1) The drawings of the embodiments of the present disclosure only involve the structures involved in the embodiment(s) of the present disclosure, and other structure(s) can be referred to common design(s).
(2) For the sake of clarity, in the drawings used to describe the embodiments of the present disclosure, the thickness of the layer or area is enlarged or reduced, that is, these drawings are not drawn according to the actual scale.
(3) In case of no conflict, the embodiments of the present disclosure and the features in the embodiments can be combined with each other to obtain new embodiments.

What have been described above are only specific implementations of the present disclosure, the protection scope of the present disclosure is not limited thereto. The protection scope of the present disclosure shall be based on the protection scope of the claims.

1. A transistor device, comprising:
a substrate;
a high electron mobility transistor provided on the substrate; and
a first depletion-mode transistor or a resistor provided on the substrate;
wherein the high electron mobility transistor comprises a barrier layer, a first source electrode, a first drain electrode, and a first gate electrode; the first source electrode and the first drain electrode are provided within an active region on the barrier layer; the first gate electrode is located between the first source electrode and the first drain electrode; the first source electrode, the first gate electrode, and the first drain electrode are isolated from each other by an insulation layer; and the first gate electrode comprises a gate cap layer provided on the barrier layer, as well as an Ohmic contact electrode, a dielectric layer, and a conductive interconnect component that are provided on the gate cap layer;
the first depletion-mode transistor comprises a second source electrode, a second drain electrode, and a second gate electrode; the second gate electrode is connected with the second source electrode; one of the second source electrode and the second drain electrode is connected with the Ohmic contact electrode, and the other of the second source electrode and the second drain electrode is connected with the conductive interconnect component;
the resistor comprises a first electrode and a second electrode opposite to each other; the first electrode is connected with the Ohmic contact electrode, and the second electrode is connected with the conductive interconnect component.

2. The transistor device according to claim 1, comprising the high electron mobility transistor and the first depletion-mode transistor,
wherein the second source electrode, the second drain electrode, and the second gate electrode are provided on the barrier layer; the second gate electrode is located between the second source electrode and the second drain electrode; and the second source electrode, the second gate electrode and the second drain electrode are isolated from each other by the insulation layer.

3. The transistor device according to claim 2, further comprising a second depletion-mode transistor provided on the substrate,
wherein the second depletion-mode transistor comprises a third source electrode, a third drain electrode and a third gate electrode; the third gate electrode is connected with the first source electrode; one of the third source electrode and the third drain electrode is connected with the Ohmic contact electrode; and the second depletion-mode transistor is electrically connected with the first depletion-mode transistor through the Ohmic contact electrode;
the other of the third source electrode and the third drain electrode is connected with the conductive interconnect component, and the second depletion-mode transistor is electrically connected with the first depletion-mode transistor through the conductive interconnect component.

4. The transistor device according to claim 1, comprising the high electron mobility transistor and the resistor, wherein the first electrode and the second electrode are provided on the barrier layer.

5. The transistor device according to claim 4, further comprising a second depletion-mode transistor provided on the substrate,
wherein the second depletion-mode transistor comprises a third source electrode, a third drain electrode and a third gate electrode; one of the third source electrode and the third drain electrode is connected with the Ohmic contact electrode, and the second depletion-mode transistor is electrically connected with the first electrode of the resistor through the Ohmic contact electrode;
the other of the third source electrode and the third drain electrode is connected with the conductive interconnect component, and the second depletion-mode transistor is electrically connected with the second electrode of the resistor through the conductive interconnect component.

6. The transistor device according to claim 3, wherein the third source electrode, the third drain electrode and the third gate electrode are provided on the barrier layer;
the third gate electrode is located between the third source electrode and the third drain electrode; and the third source electrode, the third gate electrode and the third drain electrode are isolated from each other by the insulation layer.

7. The transistor device according to claim 1, wherein a material of the gate cap layer comprises at least one of P-type doped gallium nitride, P-type doped aluminum gallium nitride, P-type doped indium gallium nitride, and P-type doped indium aluminum gallium nitride.

8. The transistor device according to claim 1, wherein a material of the dielectric layer comprises at least one of silicon dioxide, aluminum oxide, silicon nitride, aluminum nitride, and hafnium oxide.

9. The transistor device according to claim 1, further comprising a channel layer provided between the substrate and the barrier layer, wherein a material of the channel layer comprises gallium nitride.

10. The transistor device according to claim 1, wherein a gate driving voltage swing of the transistor device is larger than 7 volts.

11. The transistor device according to claim 5, wherein the third source electrode, the third drain electrode and the third gate electrode are provided on the barrier layer; the third gate electrode is located between the third source electrode and the third drain electrode; and the third source electrode, the third gate electrode and the third drain electrode are isolated from each other by the insulation layer.
